(19) United States
(12) Patent Application Publication
(10) Pub. No.: US 2006/0294443 A1
(43) Pub. Date: Dec. 28, 2006

(54) On-chip address generation

(76) Inventor: Khaled Fekih-Romdhane, Houston, TX (US)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/144,558

(22) Filed: Jun. 3, 2005

(51) Int. Cl. G01R 31/28; G06F 11/00

(52) U.S. Cl. 714/738

(57) ABSTRACT

Methods and apparatus for internally generating addresses for use in accessing elements of an integrated circuit (IC) device are provided. In response to detecting a current command, an internal address for use in executing a subsequent command may be generated. By generating the address ahead of time, before the next command is issued, the address may be generated in sufficient time to satisfy corresponding setup and hold timing requirements.

### BACKGROUND OF THE INVENTION

1. Field of the Invention

The invention generally relates to memory devices and, more particularly, to generating addresses internally during testing.

2. Description of the Related Art

The evolution of sub-micron CMOS technology has resulted in an increasing demand for high-speed semiconductor memory devices, such as dynamic random access memory (DRAM) devices, pseudo static random access memory (PSRAM) devices, and the like. Herein, such memory devices are collectively referred to as DRAM devices.

Multiple DRAM devices are typically fabricated on a single silicon wafer and undergo some form of testing (referred to as wafer test) before the devices are separated and packaged individually. This testing usually entails writing test data patterns to a particular series of address locations, reading data back from the same address locations, and comparing the data patterns read back to the data patterns written to verify device operation.

In some test systems, addresses used during wafer testing are presented via conventional device address interfaces. However, this approach requires a large amount of input/output (I/O) channels be run to each device, which generally reduces the number of devices that can be tested in parallel and increases test costs. To reduce costs, built in self test (BIST) circuits may be employed in some devices that generate addresses used for testing purposes internally. Unfortunately, with demands to increase test frequencies, internal address counters used in conventional BIST circuits may struggle to generate addresses fast enough to satisfy setup and hold timing requirements and ensure the addresses are available when the corresponding commands issued during tests are presented.

Accordingly, a need exists for techniques and apparatus for generating internal addresses for use in high frequency test operations.

### SUMMARY OF THE INVENTION

Embodiments of the invention generally provide techniques and apparatus for preemptive internal address generation.

One embodiment provides a method for generating an address internally to a device. The method generally includes detecting a command to be executed by the device when the device is in a test mode and, in response to detecting the command, executing the command with a previously-generated address and generating an address for use in executing a subsequent command.

Another embodiment provides a method for generating an address internally to a memory device for use in accessing memory elements of the device during a self-test mode. The method generally includes detecting a command to be executed by the device to access one or more memory elements, executing the command with a previously-generated address and prior to detecting a subsequent command, generating an address for use in executing the subsequent command.

Another embodiment provides a method for generating an address internally to a memory device for use in accessing normal and redundant memory elements of the device during a self-test mode. The method generally includes maintaining separate normal and redundant counter values, maintaining a selection flag indicating whether the normal or redundant counter value should be incremented. The method further includes, in response to detecting a current command, incrementing either the normal or redundant counter value based on the state of the selection flag, generating an address for use with a subsequent command by scrambling one or more bits of the incremented counter value, and executing the current command with a previously-generated address.

Another embodiment provides an integrated circuit device generally including a plurality of addressible elements and address generation circuitry. The address generation circuitry is generally configured to detect a command to be executed by the device to access one of the addressable elements and, in response, execute the command using a previously-generated address and generate an address for use in executing a subsequent command.

Another embodiment provides a memory device generally including a plurality of addressible memory elements and address generation circuitry. The address generation circuitry is generally configured to detect a command to be executed by the device to access one of the addressable elements when the memory device is in a test mode and, in response, execute the command using a previously-generated address and generate an address for use in executing a subsequent command.

Another embodiment provides a memory device having one or more built in self test (BIST) modes. The device genearlly includes a plurality of normal and redundant memory elements, counter circuitry, scrambling circuitry, and latching circuitry. The counter circuitry is generally configured to increment one of a normal counter value and a redundant counter value, in response to detecting a current command to access one or more of the memory elements. The scrambling circuitry is generally configured to generate normal and redundant addresses for use in accessing normal and redundnat memory elements, respectively, based on the normal and redundant counter values. The latching circuitry is generally configured to latch at least one of the normal and redundant addresses generated by the scrambling circuitry in response to detecting the current command and output the latched address in response to detecting a subsequent command.

Another embodiment provides a memory device. The memory device generally including a plurality of addressible memory elements and address generation means for, in response to detecting a current command to access one or more of the memory elements, preemptively generating an address for use in accessing one or more of the memory elements with a subsequent command.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an exemplary DRAM device with an internal address generator in accordance with embodiments of the present invention;

FIG. 2 is a flow diagram of exemplary operations for generating internal addresses in accordance with embodiments of the present invention;

FIG. 3 is a timing diagram of generating internal addresses in accordance with embodiments of the present invention;

FIG. 4 illustrates exemplary row address generation circuitry in accordance with embodiments of the present invention;

FIG. 5 illustrates exemplary column address generation circuitry in accordance with embodiments of the present invention; and

FIG. 6 illustrates exemplary logic for toggling between accessing normal and redundant memory elements.

### DETAILED DESCRIPTION OF THE PREFERRED EMBODIMENT

Embodiments of the invention generally provide techniques and apparatus for internally generating addresses, for example, for use in testing an integrated circuit (IC) device. In response to detecting a current command, an internal address for use in executing a next command may be generated. By generating the address ahead of time, before the next command is issued, the address may be generated in sufficient time to satisfy corresponding setup and hold timing requirements.

To facilitate understanding, embodiments of the present invention will be described with reference to dynamic random access memory (DRAM) devices as a specific, but not limiting, application example. However, those skilled in the art will recognize that concepts described herein may be applied to advantage in a variety of different memory devices and other integrated circuit (IC) devices that utilize internally generated addresses.

### An Exemplary DRAM Device

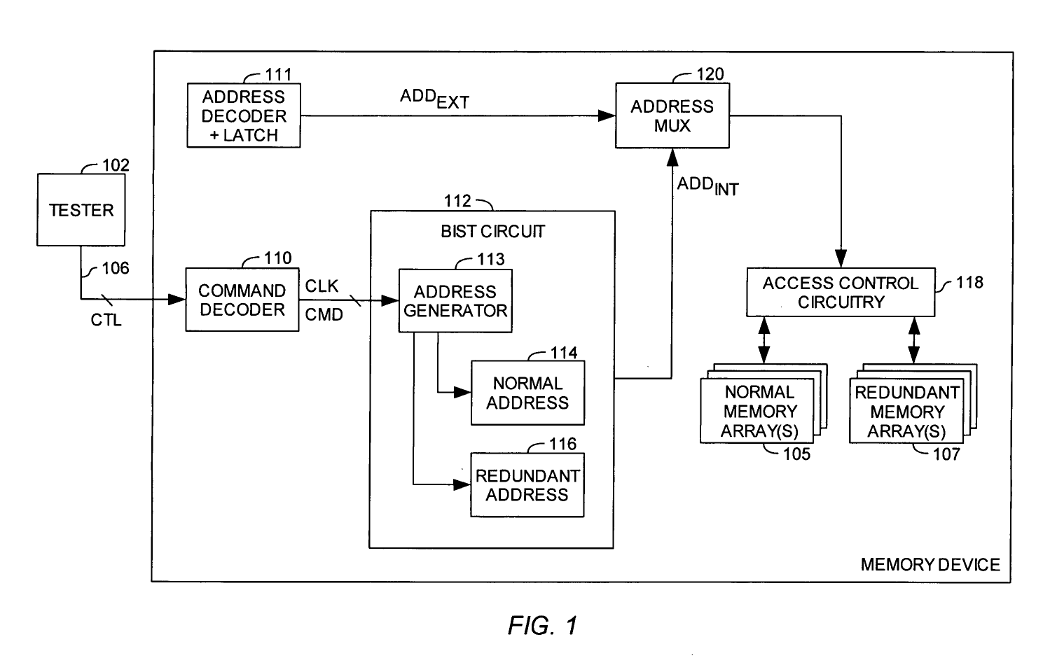

FIG. 1 illustrates an exemplary DRAM device 104 with built-in self-test (BIST) circuitry 112 in accordance with embodiments of the present invention. The BIST circuitry 112 may be used to perform tests, for example, by accessing normal memory arrays 105 and redundant memory arrays 107. As is well known, redundant arrays 107 may be used to replace normal arrays 105 that are found to be failing during testing.

During normal operations, addresses of targeted memory cells supplied by an external device, such as a memory controller, are latched in by address decoder and latch circuitry 111. During BIST operations, however, addresses are generated by an internal address generator 113. An address multiplexer 120 may select between addresses generated by the internal address generator 113 and an address generated by the address decoder and latch circuit 111 based on an externally supplied address. In other words, the multiplexer 120 may be controlled such that the internally generated address is selected during BIST operations, while the address generated by the address decoder and latch circuit 111 is selected during normal (read/write) accesses.

Access control circuitry 118 may be generally configured to activate rows and select columns to access elements in the normal and redundant arrays 105-107 corresponding to the address received from the address multiplexer 120. The access control circuitry 118 may include circuitry to generate output addresses from the address received from the address multiplexer 120 (e.g., based on upper bits of the address received). The access control circuitry 118 may also include circuitry to route access to failing normal memory arrays 105 to redundant memory arrays 107 that have been selected for replacement.

During BIST operations, the internal address generator 113 may be configured to generate new normal and redundant addresses (e.g., by incrementing normal and redundant address counter values 114-116) in response to detecting commands. Depending on a test mode, the commands may be generated internally, by the BIST circuit 112, or supplied externally on a control interface 106 and decoded by a command decoder 110.

As previously described, with increasing test frequencies, internal address counters used in conventional BIST circuits may be inadequate or incapable to generate addresses fast enough to satisfy setup and hold timing requirements and ensure the addresses generated are available when the corresponding commands issued during tests are presented.

### Preemptive Address Generation

Embodiments of the present invention may facilitate satisfying such setup and hold timing requirements by “preemptively” generating an address for use with a command before that command has been detected. For example, the address for a subsequent command may be generated in response to detecting a current command. By effectively anticipating the subsequent command, the corresponding address used by that command may be calculated ahead of time and, thus, already available by the time the subsequent command is detected, allowing setup and hold times to be easily satisfied.

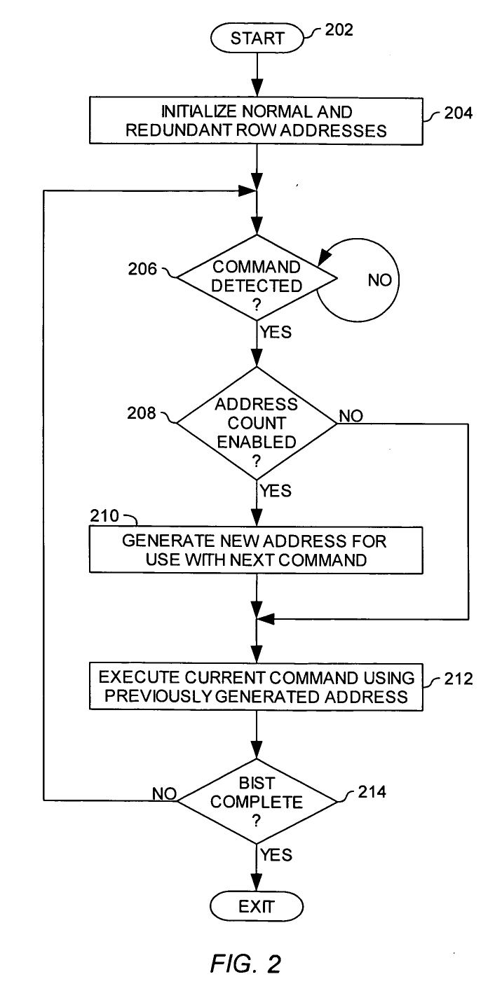

FIG. 2 is a flow diagram of exemplary operations for preemptively generating internal addresses in accordance with embodiments of the present invention. For example, the operations may be performed by the BIST circuit 112 and corresponding address generator 113.

The operations begin, at step 202, for example, when the device 101 is put into a test mode, by tester 102, to initiate a self test. The self-test may include accessing both normal memory arrays 105 and redundant memory arrays 107, for example, writing known data patterns to rows in the arrays 105-107 in a predetermined order, reading data back from the arrays, and comparing the data read to the data written to check for errors. For some embodiments, the particular order in which elements in the arrays 105-107 are accessed may be determined by a particular test mode selected.

At step 204, normal and redundant addresses are initialized, for example, by initializing normal and redundant address counter values. For some embodiments, the normal and redundant addresses may be initialized to particular start addresses based on a selected test mode, for example.

If a command is detected, at step 206, it may be appropriate to generate a new address for use with a subsequent command. In some cases, however, to provide additional control with regard to testing, it may be possible to selectively enable and disable address adjustments (e.g., via an address count flag provided with a command). Assuming such an embodiment, if address counting is disabled, a new address for use with a subsequent command is not automatically generated. Otherwise, if address counting is enabled, a new address is generated, at step 210.

At step 212, the current command (detected at step 206) is executed using a previously generated address. As will be described in greater detail below, a redundant element counting or “overflow” flag may determine whether a normal or redundant row address is used to execute the current command. In other words, logic may toggle this flag to periodically alternate between accessing normal and redundant arrays. For some embodiments, both normal and redundant addresses may be generated ahead of time and latched, with the actual address that is output selected based on the overflow flag.

As illustrated, operations 206-212 may be repeated until the BIST is complete, as determined at step 214, for example, after all rows in the normal and redundant arrays 105-107 have been tested.

As illustrated in FIG. 1, for some embodiments the BIST circuit 112 may maintain separate registers 114 and 116 to store values (e.g., counter values) from which normal and redundant addresses, respectively, are generated. These values may be adjusted (e.g., incremented or decremented) independently upon detecting commands (e.g., when address counting is enabled). For example, during portions of a test when rows in the normal arrays 105 are accessed, a value in the normal row address register 114 may be incremented, while a value in the redundant row address register 116 may be incremented during portions of the test when rows in the redundant arrays 107 are accessed.

As will be discussed in greater detail below, the order in which normal and redundant rows are addressed may be determined by a particular test algorithm and scrambling circuitry that reorders bits of internally maintained normal and redundant row addresses. Utilizing such circuitry may facilitate implementing different test algorithms while simplifying address generation. For example, simple counting circuitry may be utilized to increment normal and redundant array row addresses, while separate scrambling circuitry may scramble one or more bits to access rows in a particular desired order.

### Preemptive Address Generation Timing Diagram

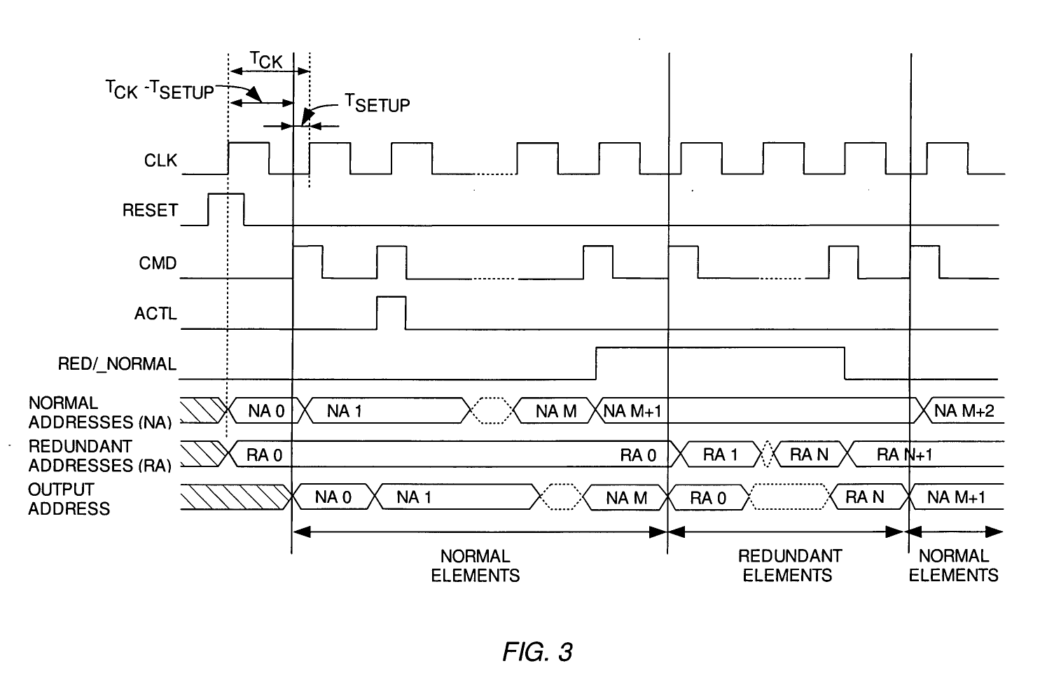

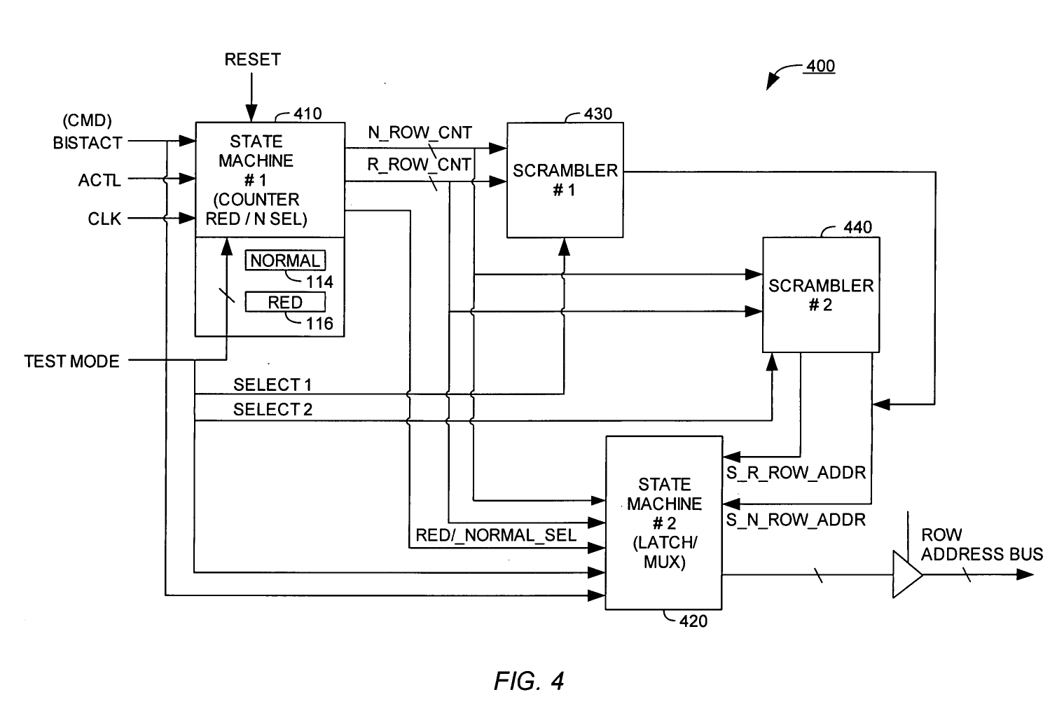

FIG. 3 shows a timing diagram that illustrates how separate normal and redundant row addresses may be adjusted independently. As illustrated, in response to a reset signal (e.g., RESET issued at the beginning of BIST), the internal normal and redundant row addresses may be initialized to some initial values (N-ADDRESS0 and R-ADDRESS0, respectively, which may depend on a particular test mode selected). As will be described in greater detail, with reference to FIG. 4, counter values in registers 114-116 may be initialized while the actual addresses eventually output may be generated by scrambling circuitry.

Both normal and redundant addresses may be available (e.g., latched) and ready to be output in response to a subsequently detected command with minimal delay. Even with any additional latency added by such scrambling circuitry, the generated output address may be available in time for the subsequent command that requires it. As a result, even in a worst case scenario resulting in the most demanding timing requirements, such as when the command requiring a generated address is presented in the next clock cycle, address setup and hold requirements may be easily met.

Assuming that normal rows are to be accessed first, as indicated by a low logic level of a redundant element counting flag (RED/_NORMAL_SEL), the initial normal address (N-ADDRESS0) is output in response to a first command (CMD0). An address for use in a subsequent command may also be generated. As illustrated, in response to a rising edge of a clock signal (CLK) in which CMD0 was presented, a next normal address (N-ADDRESS1) may be generated, latched and ready to output on a subsequent detected command.

For some embodiments, address counting may be inhibited via assertion of a counter inhibit flag (ACTL). Thus, as illustrated, when a subsequent command (CMD I) is detected and ACTL is asserted, the internal normal address, as well as the output address, may remain unchanged. In other words, CMDI may be essentially ignored by the internal address generator, which may be useful, for example, if it is desired to access the same row multiple times (e.g., different columns in the same row). For the next command (CMD1), however, with ACTL de-asserted, the internal normal address is again changed. This process may repeat, as normal rows with row addresses N-ADDRESS0-ADDRESSm are accessed.

As illustrated, in conjunction with the command to access the normal element at N-ADDRESSm (CMD m), the redundant element counting flag (RED/_NORMAL_SEL) may be asserted, indicating redundant elements are to be accessed rather than normal elements. Therefore, in response to the next command (CMD m+1), the initial redundant address (R-ADDRESS0) is output. On the rising edge of the corresponding clock, the redundant address for use with the next command is generated (e.g., to R-ADDRESS1).

As illustrated, after n redundant elements have been accessed, the redundant element counting flag (RED/_NORMAL_SEL) may be de-asserted, indicating normal elements are to be accessed again (e.g., beginning with the previously calculated N-ADDRESSm+1). As will be described in greater detail below, when to toggle between accessing normal and redundant elements may be determined based on a particular test mode and corresponding selection circuitry that generates the redundant element counting flag (RED/_NORMAL_SEL) signal.

### Exemplary Address Generation Logic

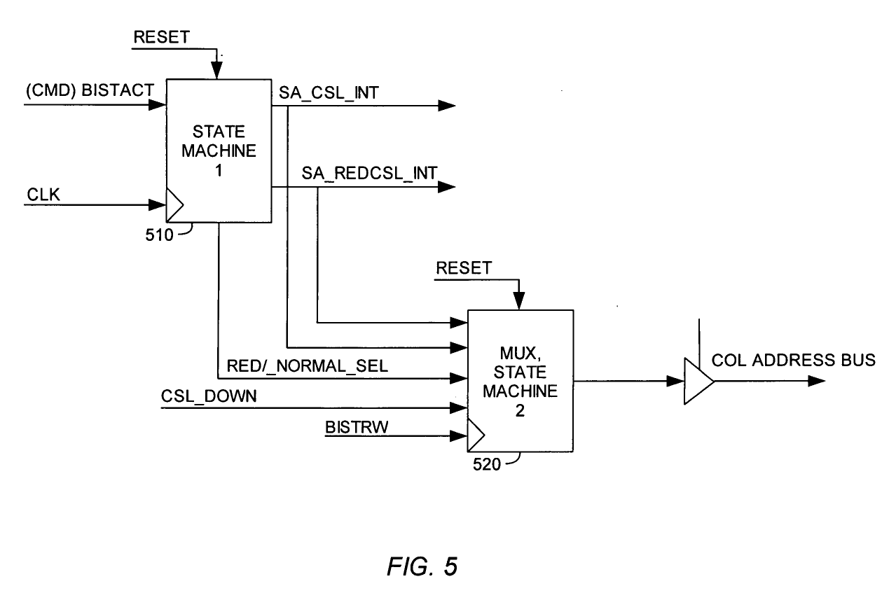

FIGS. 4 and 5 illustrate exemplary internal address generation logic (circuitry) 400 and 500 capable of preemptively generating internal normal and redundant row and column addresses, respectively. Referring first to FIG. 4, the exemplary row address generation logic 400 may include first and second state machines 410 and 420 to generate normal and redundant row addresses and drive those addresses on an address bus during BIST accesses.

The first state machine 410 may be generally configured to maintain and adjust independent counter values in registers 114 and 116, respectively, from which normal and redundant row addresses may be generated. For example, in response to detecting a current command, as indicated by a BISTACT signal, the first state machine 410 may increment either the normal counter value or redundant value for use in generating an address for use in a subsequent command. Further, as described above, counting may be inhibited altogether via the ACTL flag, which may be presented with the command.

The first state machine 410 may also control which of the counter values is incremented and when, for example, based on one or more test mode bits (e.g., from a control register). For example, in one test mode, the first state machine 410 may be configured to access half of the normal elements, half of the redundant elements, the other half of the normal elements, then the other half of the redundant elements. In some cases, the counter values may be incremented in steps of more than just one, for example, (e.g., by 4, 8, 16, etc. based on a desired test algorithm indicated by the test mode bits).

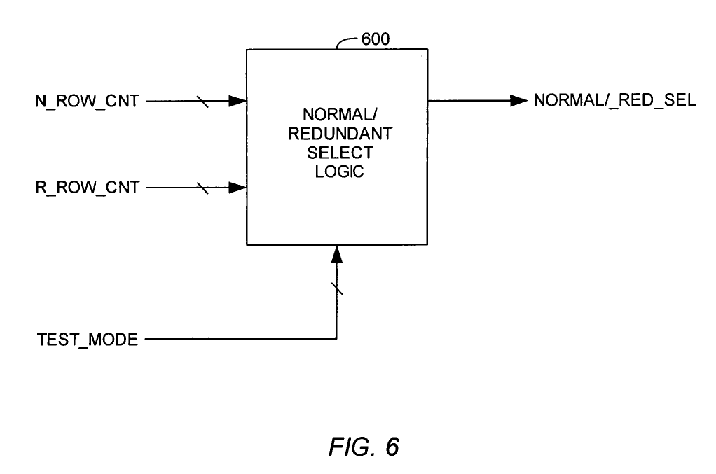

For some embodiments, the first state machine 410 may toggle the RED/_NORMAL_SEL signal to indicate whether a normal or redundant address should be output. As illustrated in FIG. 6, exactly how the RED/_NORMAL_SEL signal may be determined by select logic 600 based on the particular characteristics or targeted effect of a selected test algorithm (which may be identified by one or more test mode bits). In other words, the select logic 600 may monitor the normal and redundant row addresses as they are incremented and toggle the RED/_NORMAL_SEL signal when appropriate.

As will be described in greater detail below, the second state machine 420, may be generally configured to act as a multiplexor and latch a normal or redundant address (which may be scrambled or unscrambled) generated based on the state of the RED/_NORMAL_SEL signal. In other words, the second state machine 420 may act as multiplexor, driving either the normal or redundant row address on the row address bus, depending on the state of the RED/_NORMAL_SEL signal, when a command is detected.

### Optional Scrambling Logic

For some embodiments, the address generation circuitry may include one or more stages of scrambling logic that generate scrambled normal and redundant row addresses based on the normal and redundant row counter values output from the first state machine 410. The scrambling logic may generate scrambled normal and redundant row elements by swapping (or scrambling) one or more bits of the normal and redundant row counter values received as inputs. For illustrative purposes only, two scrambling logic circuits 430 and 440 are shown, that each generate a pair of scrambled normal and redundant row addresses by, for example, scrambling different sets of bits.

For some embodiments, the scrambling logic circuits may output their respective scrambled normal and redundant row addresses to the second state machine 420 on a common address bus. The first state machine 410 may generate one or more signals (e.g., separate select signals SELECT1 and SELECT2 as shown) to select only one of the scrambling logic circuits to drive their scrambled normal and redundant row addresses onto the common bus. For example, the first state machine 410 may select a particular one of the scrambling logic circuits corresponding to a particular test mode selected. The separate scrambling logic circuits may allow relatively complex scrambling operations to be used to generate the output address while still allowing relatively simple counting logic to be used in the first state machine 410 to increment/adjust the normal and redundant row addresses.

As illustrated, for some embodiments, both the (unscrambled) normal and redundant row addresses and the scrambled normal and redundant row addresses may be provided to the second state machine 420. In other words, the second state machine 420 may latch both scrambled and unscrambled normal and redundant row addresses before they are needed (e.g., by a subsequent command), which may allow these addresses to be quickly selected when needed. In such cases, the test mode bits may be used to select between the scrambled or unscrambled row address, while the RED/_NORMAL_SEL signal generated by the first state machine 410 may be used to select between the normal and redundant row addresses, when a corresponding command is detected.

As illustrated in FIG. 5, similar state machines 510 and 520 may be utilized to preemptively generate column address during BIST testing. For some embodiments, scrambling logic circuits similar to those shown in FIG. 4 may also be utilized to generate scrambled column addresses. The scrambled column addresses may be generated and selected in a similar manner to that described above for scrambled row addresses.

### CONCLUSION

By generating an address for use with a particular command ahead of time, for example, in response to detecting an earlier issued command, setup and hold timing requirements for such addresses may be easily satisfied.

While the foregoing is directed to embodiments of the present invention, other and further embodiments of the invention may be devised without departing from the basic scope thereof, and the scope thereof is determined by the claims that follow.

What is claimed is:

1. A method for generating an address internally to a device, comprising:
detecting a command to be executed by the device when the device is in a test mode; and
in response to detecting the command, executing the command with a previously-generated address and generating an address for use in executing a subsequent command.

2. The method of claim 1, wherein generating the address for use in executing the subsequent command comprises incrementing a counter value.

3. The method of claim 2, wherein generating the address for use in executing the subsequent command further comprises scrambling one or more bits of the counter value.

4. The method of claim 2, wherein generating the address for use in executing the subsequent command comprises:
scrambling one or more bits of the counter value with a first set of scrambling logic to generate a first scrambled address;
scrambling one or more bits of the counter value with a second set of scrambling logic to generate a second scrambled address; and
selecting the first or second scrambled address based on a particular test mode.

5. A method for generating an address internally to a memory device for use in accessing memory elements of the device during a self-test mode, comprising:
detecting a command to be executed by the device to access one or more memory elements;
in response to detecting the command, executing the command with a previously-generated address; and
prior to detecting a subsequent command, generating an address for use in executing the subsequent command.

6. The method of claim 5, wherein detecting the command comprises detecting an externally generated command to access one or more of the memory elements.

7. The method of claim 5, wherein detecting the command comprises detecting an internally generated command to access one or more of the memory elements.

8. The method of claim 6, wherein:
the memory elements comprise normal and redundant memory elements; and
generating the address for use in executing the subsequent command comprises incrementing at least one of a normal address counter value maintained for generating a normal memory element and a redundant address counter value maintained for generating a redundant memory element.

9. The method of claim 8, further comprising generating a signal indicative of whether the normal address counter value or redundant address counter value should be incremented.

10. The method of claim 5, wherein generating the address for use in executing the subsequent command comprises:
scrambling one or more bits of the counter value with a first set of scrambling logic to generate a first scrambled address;
scrambling one or more bits of the counter value with a second set of scrambling logic to generate a second scrambled address; and
selecting the first or second scrambled address based on a particular test mode.

11. A method for generating an address internally to a memory device for use in accessing normal and redundant memory elements of the device during a self-test mode, comprising:
maintaining separate normal and redundant counter values;
maintaining a selection flag indicating whether the normal or redundant counter value should be incremented; and
in response to detecting a current command,
incrementing either the normal or redundant counter value based on the state of the selection flag,
generating an address for use with a subsequent command by scrambling one or more bits of the incremented counter value, and
executing the current command with a previously-generated address.

12. The method of claim 11, further comprising toggling the state of the selection flag based, at least in part, on an identified test mode.

13. The method of claim 11, further comprising selecting one of a plurality of scrambling logic circuits for performing the scrambling based, at least in part, on an identified test mode.

14. An integrated circuit device, comprising:
a plurality of addressible elements; and
address generation circuitry configured to detect a command to be executed by the device to access one of the addressable elements and, in response, execute the command using a previously-generated address and generate an address for use in executing a subsequent command.

15. The device of claim 14, wherein the address generation circuitry is configured to generate the address for use in executing the subsequent command by incrementing a counter value.

16. The device of claim 15, wherein the address generation circuitry includes scrambling logic configured to generate the address for use in executing the subsequent command by swapping at least two bits of the counter value.

17. A memory device, comprising:
a plurality of addressible memory elements; and
address generation circuitry configured to detect a command to be executed by the device to access one of the addressable elements when the memory device is in a test mode and, in response, execute the command using a previously-generated address and generate an address for use in executing a subsequent command.

18. The memory device of claim 17, wherein:
the addressable memory elements include normal and redundant elements; and
the address generation circuitry is configured to maintain separate normal and redundant counter values for use in generating address for accessing normal and redundant memory elements, respectively.

19. The memory device of claim 18, wherein the address generation circuitry is configured to alternate between accessing normal memory elements and accessing redundant memory elements based on a particular test mode.

20. The memory device of claim 19, further comprising circuitry configured to:
latch both normal and redundant memory addresses generated based on the normal and redundant counter values, respectively; and
in response to detecting the command, output either the latched normal or redundant memory address based on an input signal indicative of whether normal or redundant memory elements are being accessed by the address generation circuitry.

21. A memory device having one or more built in self test (BIST) modes, comprising:
a plurality of normal and redundant memory elements;
counter circuitry configured to increment one of a normal counter value and a redundant counter value, in response to detecting a current command to access one or more of the memory elements;
scrambling circuitry configured to generate normal and redundant addresses for use in accessing normal and redundnat memory elements, respectively, based on the normal and redundant counter values; and
latching circuitry configured to latch at least one of the normal and redundant addresses generated by the scrambling circuitry in response to detecting the current command and output the latched address in response to detecting a subsequent command.

22. The memory device of claim 21, wherein the latching circuitry is configured to latch both normal and redundant addresses generated by the scrambling circuitry.

23. The memory device of claim 22, wherein the scrambling circuitry comprises at least two separate scrambling circuits, selectable based on an identified BIST mode.

24. A memory device, comprising:
a plurality of addressible memory means for storing data; and
address generation means for, in response to detecting a current command to access one or more of the memory means, preemptively generating an address for use in accessing one or more of the memory means with a subsequent command.
